(19) United States
(12) Patent Application Publication
(10) Pub. No.: US 2026/0278197 A1
(43) Pub. Date: Sep. 17, 2026

(54) METHOD OF PLANNING A CONVEYOR ARRANGEMENT

(71) Applicant: INTERROLL HOLDING AG, Sant'Antonino (CH)

(72) Inventor: Christian Ripperda, Hückelhoven (DE)

(21) Appl. No.: 19/168,164

(22) PCT Filed: Mar. 18, 2024
(86) PCT No.: PCT/EP2024/057116

§ 371 Date: Sep. 23, 2025

(30) Foreign Application Priority Data
Mar. 28, 2023 (EP) 23164546.6

(51) Int. Cl. G06F 30/17; G06F 3/0484

(52) U.S. Cl. CPC G06F 30/17; G06F 3/0484

(57) ABSTRACT

A method of planning a conveyor arrangement adapted to convey an object from at least one first location to at least one second location; in particular wherein during intended use of the operation an operation interacts with the object located within the conveyor arrangement; the method including the following step of providing an IT planning tool for usage by a planner; wherein by using the IT planning tool, representations of a plurality of conveyor components, in particular conveyor zones are arranged in a manner to form a, in particular graphical, representation of the conveyor arrangement (1); wherein the step of outputting a noise level by the IT planning tool (8).

### CROSS-REFERENCE TO RELATED APPLICATIONS

This is a US national phase entry application under 35 U.S.C. 371 of international patent application no. PCT/EP2024/057116 filed 18 Mar. 2024, which claims priority to European patent application no. 23164546.6, filed Mar. 28, 2023; each of which is herein incorporated by reference in its entirety.

### TECHNICAL FIELD

The invention refers to a method of planning a conveyor arrangement.

### BACKGROUND OF THE DISCLOSURE

EP 3 222 564 B1 discloses a conveyor for conveying an object from a start position to a target place. The conveyor comprises a plurality of zones into which the conveyor is divided, the object being conveyed across the zones; each of the zones comprising: a linear conveying zone that linearly conveys the object; a conveying direction changing zone selecting a conveying direction of the object to send out the object in the selected conveying direction; a conveyance destination storage unit that is configured to store the conveyance destination information temporarily; an information receiving unit that is configured to receive the conveyance destination information from an upstream zone; and an information transmitting unit that is configured to transmit the conveyance destination information to a downstream zone. The conveyor transfers the conveyance destination information from the upstream zone to the downstream zone with the movement of the object across the zones.

WO 2021/048042 A1 discloses a virtual layouter tool. Here a conveyor arrangement can be created in the virtual world using 3D data of individual conveyor modules. The 3D data of the conveyor devices are arranged in a spatial relation to each other which conforms a possible relation of the relating real module devices in the real world. The created conveyor arrangement in the virtual world can be used in a simulation mode for predicting an efficient use and configuring a sufficient capacity of the conveyor arrangement. Another layouter tool is disclosed in EP 3 982 223 A1.

A tool for simulating a conveyor arrangement is disclosed in JP 2002 297 226 A. A virtual layout of a conveyor arrangement is shown under https://www.youtube.com/watch?v=A4i2wrfRuPs.

It is an object of proving an improved conveyor device and in particular a method of planning/assembling the same. The invention comprises a method according to claim 1; embodiments are subject of the subclaims and the description.

### SUMMARY OF THE DISCLOSURE

The conveyor arrangement to be planned with the help of the inventive method is adapted to convey an object from at least one first location to at least one second location. A first location may be a feed in station; a second location may be a destination. An operator may get in interaction with the object to be conveyed.

The inventive method comprises the step of providing an IT planning tool for usage by an planner; wherein by using the IT planning tool, representations of a plurality of conveyor components, in particular conveyor zones, are arranged in a manner to form a representation of said conveyor arrangement.

According to the invention the IT planning tool is adapted to output a noise level. With the help of the provided noise level a noise impact to an operator can be determined during the planning phase.

In an embodiment the output noise level represents an expected noise level at a noise position in a spatial relation to the planned conveyor arrangement. Here the noise level is helpful to distinguish or define the noise level at various locations. Here the invention takes into account that a certain distance from a noise source has a significant influence in the noise level at a certain location. This feature enables an early planning of most comfortable operator workstations located on site at the conveyor arrangement.

In an embodiment the steps of planning comprise the steps of a) defining a noise position in a spatial relation to the conveyor arrangement, b) determining a noise level at the noise position.

In an embodiment the noise position is defined by an user interaction. Here the planner can define any position where the planer intends to evaluate the noise impact. In particular by marking a position in particular by placing a symbol e.g. a virtual microphone, at a position to be defined as the noise position.

In an embodiment the noise position is defined automatically by the IT tool. In particular some areas are sometimes associated with the cooperation of an operator. For example, a destination is often a picking station, where an operator is located to manually pick the objects and transfer them into a truck or a cage box. The IT tool may then automatically define such a station as a noise position to inform the planner about the noise level on a regular basis.

In an embodiment a noise model of one or a plurality of conveyor components is provided to determine a noise emission of said one or a plurality of conveyor components. Based on said determined noise emission, a location of said noise emission and said noise position, the noise level at said noise position is determined.

In general, the noise level is to be understood as a statement about the expected noise level, which is based on planning a conveyor arrangement, provided in the IT tool. It is to be mentioned that the noise level may deviate from the exact noise level which will occur at the later real conveyor arrangement.

Within the present application it is to be distinguished between a planer and an operator. The planner is a person who is handling the IT tool during planning. The operator is a person who is on site at the conveyor arrangement and may get in interaction with the objects to be conveyed during intended usage of the planned conveyor arrangement.

Unless stated otherwise, the terms upstream and downstream refer to the direction of travel.

### BRIEF DESCRIPTION OF THE DRAWINGS

An example embodiment of the invention is described in more detail with the help of the figures; herein show

FIG. 1 a conventional conveyor zone in perspective view;

FIG. 2 a conventional basic conveyor arrangement;

FIG. 3. schematic representations of different conveyor zones;

FIG. 4 a principal sketch of a conveyor arrangement;

FIG. 5 a personal computer on which the layouter is running in an initial planning step;

FIGS. 6 to 9 the personal computer of FIG. 5 in subsequent planning steps.

### DETAILED DESCRIPTION

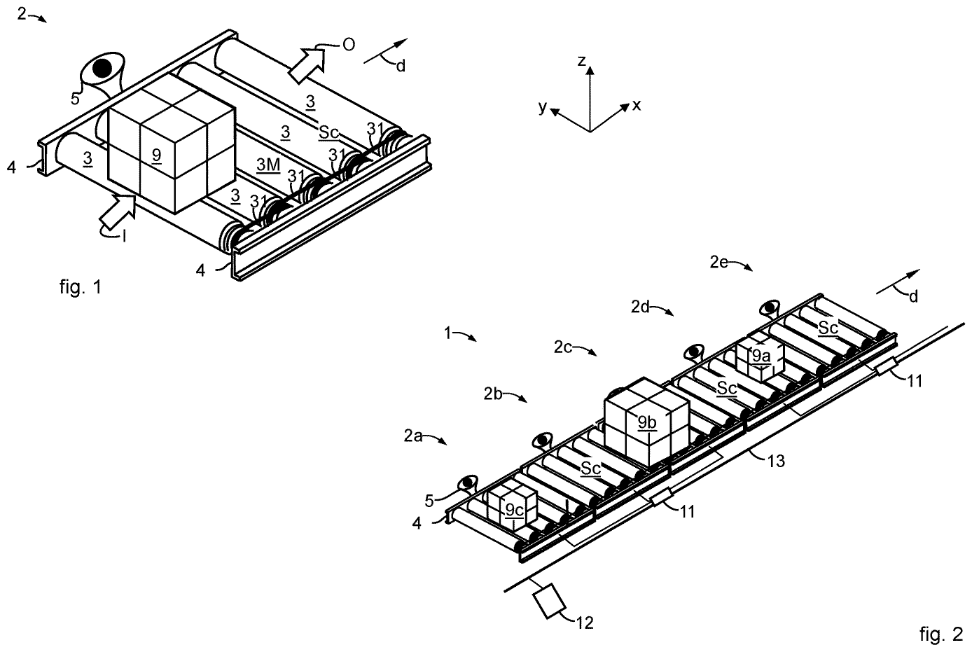

FIG. 1 shows an exemplary conveyor zone 2, comprising several conveyor rollers 3 which are driven together by a common motor. For this purpose, one of the conveyor rollers is designed as a motorized conveyor roller 3M. The motorized conveyor roller 3M is driven in particular by a three-phase motor arranged within the conveyor roller 3. Via one or more drive connectors 31, e.g. a drive belt, the conveyor rollers 3 of a conveyor zone 2 are drive-connected to each other and are jointly driven by the motorized conveyor roller 3M. An upper side of the rollers 3 form a conveyor surface Sc, on which an object 9 is in particular linearly conveyed from an inlet I to an outlet O along a conveying direction d.

In another embodiment a conveyor belt is used instead of rollers; accordingly, the conveying surface Sc is formed by the upper side of the conveyor belt (not shown in FIGS. 1 and 2).

By means of a presence sensor 5, the presence of a conveyed object 9 arranged on the conveyor zone 2 can be determined as soon as the object comes into the field of view of the sensor 5.

The motorized conveyor rollers 3M are each controlled by at least one or a plurality of zone controllers 11. A local zone controller 11 can control the motorized conveyor rollers 3M of several conveyor zones 2. A plurality of zone controllers 11 are arranged in a conveyor arrangement 1 (FIG. 2), which communicate with each other via a bus connection 13.

FIG. 2 shows a basic conveyor arrangement 1, where conveyor zones 2a . . . e as described previously are used. A plurality of zone controllers 11 control the operation of the conveyor zones 2. A PLC 12 (programmable logic control) may be provided to control the overall operation of the conveyor arrangement 1.

Scanners (not shown) may be arranged along the zones 2 and provide identification data relating to objects 9a . . . c passing the scanner in the zones 2. These identification data are sent via bus connection 13 to the PLC 12. The PLC 12 has access to an object data base (not shown), which provides destination data based in the identification of the objects 9. Based on the acquired data the PLC 12 provides an operation instruction to a local zone controller 11, how to handle the object 9, i.e., to which of the outlets O said object 9 is to be conveyed.

In an alternative embodiment as described in the European patent application 22 180 381.0, no PLC 12 or similar is required. Instead of a PLC 12 the zone controllers 11 are connected to a common higher-level object data broker, in particular via the bus connection 13, with which the zone controllers 11 are also connected to one another. The data broker provides destination data related to the identified objects 9 and the zone controllers 11 are adapted to control operation of the zones 2 based on the provided destination data.

In particular the zone controllers 11 control the motorized conveyor rollers 3M in such a way that the successively approaching conveyed objects 9 do not collide with each other, which is usually called “zero pressure accumulation”. The control takes place in such a way that essentially only one conveyed object 9 is present per conveyor zone 2. However, slight overlaps may occur. For example, an upstream object 9b located on an upstream conveyor zone 2c may already enter a downstream zone 2d even though the downstream conveyed object 9a has not yet left this downstream conveyor zone 2d completely. Among other things, the sensor signals of the presence sensors 5 serve as input variables here, although it is ensured that the two conveyed objects 9 do not touch and thus do not damage each other.

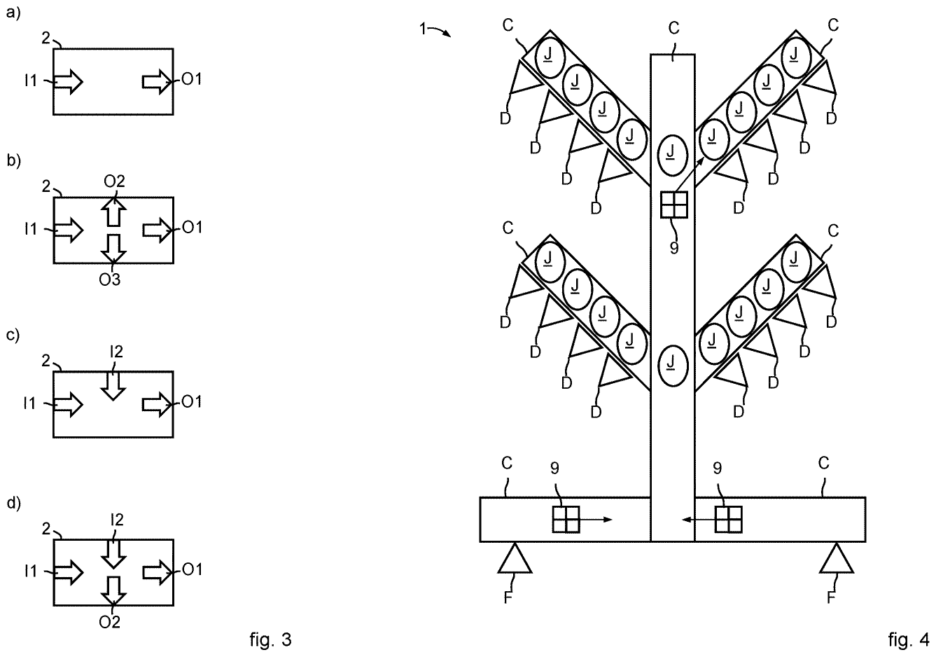

In the following course of the invention, reference is made to conveyor zones 2, using a schematic representation of said conveyor zone 2 as shown in FIG. 3. Here FIG. 3a represents schematically a conveyor zone 2 of FIG. 1, which has one first inlet 11 and one first outlet O1. No more inlets and outlets are provided. The conveyor zone 2 can also be curved or from other shape.

FIG. 3b shows the representation of another conveyor zone 2 having an extended scope of operation. Here in addition to the conveyor zone 2 of FIG. 3a the conveyor zone 2 has an additional, second outlet O2. The object 9 can be conveyed selectively from said first inlet 11 to one of said first and second outlets O1, O2. Optionally, the conveyor zone 2 has an additional, third outlet O3. In this option, the object 9 can be conveyed selectively from said first inlet 11 to one of said first, second and third outlets O1, O2, O3.

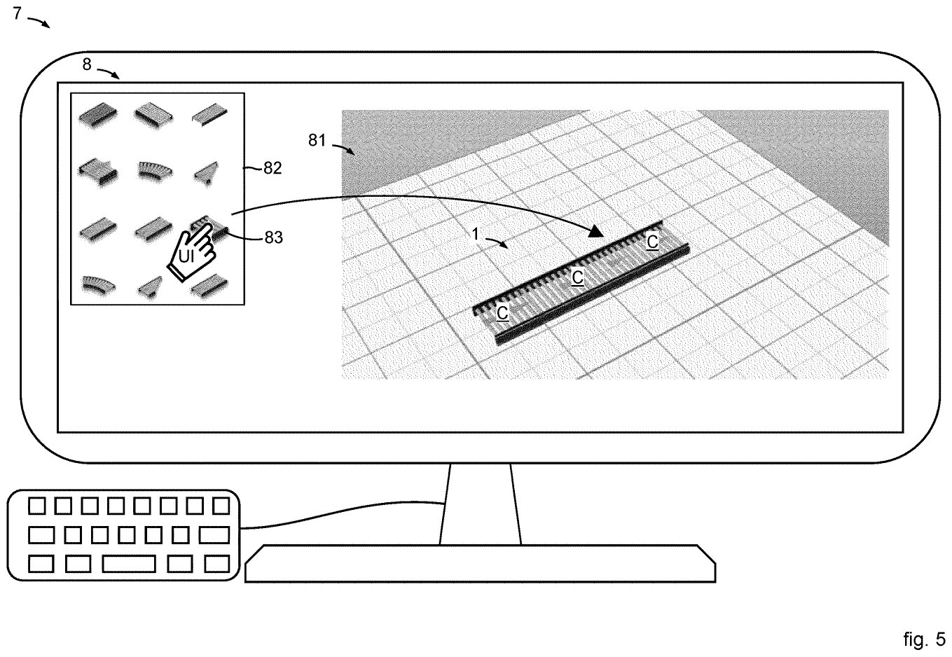

As an example, said conveyor zone 2 of FIG. 3b can be formed by a conveyor zone 2 as shown in FIG. 1, which additionally is provided with a transfer device as described with reference to FIG. 5 of EP 3 222 564 B1 (in that document and figure the transfer device has reference sign 20).

FIG. 3c shows the representation of a conveyor zone 2 having an extended scope of operation. Here in addition to the conveyor zone 2 of FIG. 3a, the conveyor zone 2 has an additional second inlet I2. Objects 9 can be conveyed from one of said first and second inlets I1, I12 to said first outlet O1.

The transfer device as described with reference to FIG. 3b may also be suitable to provide said additional second inlet I2.

FIG. 3d shows the representation of a conveyor zone 2 having an extended scope of operation. Here in addition to the conveyor zone 2 of FIG. 1 the conveyor zone 2 has an additional second inlet I2 and an additional second outlet 02 and is an example as a combination of the embodiments of FIGS. 3b and 3c.

All conveyor zones 2 are controlled by a zone controller 11 as shown in FIG. 1 or 2, in particular wherein one zone controller 11 may be adapted to control the operation of more than one zone 2.

Starting from FIG. 4 the planning of a conveyor arrangement 1, which is performed by a person, herein called the planner.

FIG. 4 shows a principal sketch of what the conveyor arrangement 1 should finally look like.

The conveyor arrangement 1 according to the sketch has two feed in stations F, where an operator can input objects 9 to be conveyed. From the feed in stations F the objects 9 are conveyed to several destinations D by several conveyors C. A plurality of junctions J are provided, at which the objects 9 are selectively transferred onto one of a plurality of routes along the conveyors C. Such a sketch may be only available in the head of a planner.

Reference is now made to FIG. 5. For detailed planning, the planner uses an IT tool 8, which is an application program running on a personal computer 7, where the term personal computer also includes tablet PC or similar devices. The IT tool 8 is herein also called the “layouter”.

The layouter 8 provides a construction area 81 in which the planner can create a digital representation of a conveyor arrangement 1. The layouter 8 provides a selection area 82, in which components are provided for being selected by the planner. By a user interaction UI, the planner can select a graphical representation 83 of a certain component and transfer the selected component via drag & drop into the construction area 81.

After a few repetitions, a small conveyor arrangement 1 has been created already in the construction area 81, comprising a straight line of roller conveyors C.

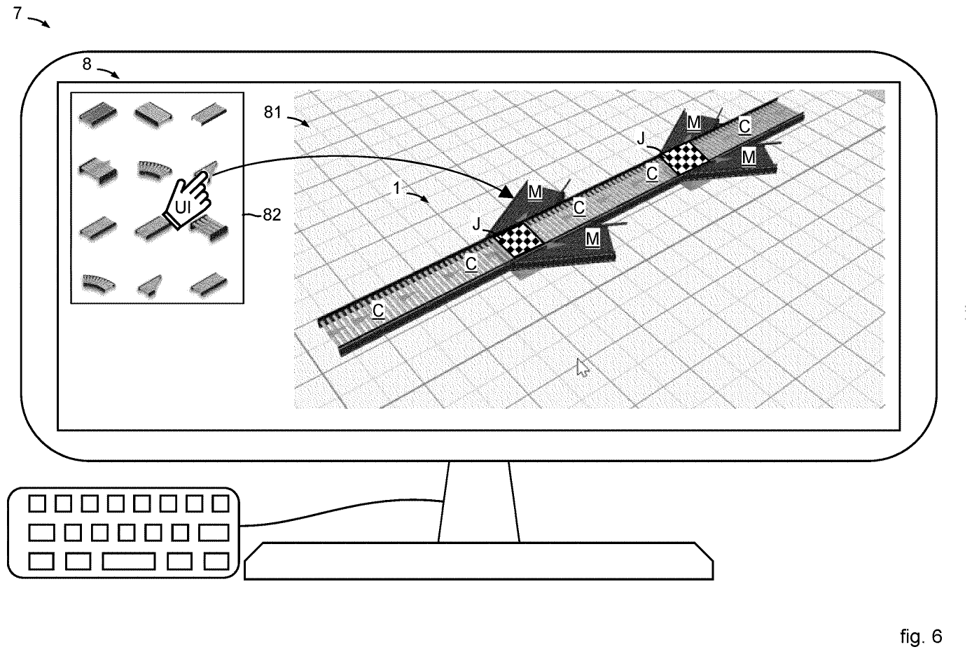

FIG. 6 shows in the construction area 81 the representation of the further developed conveyor arrangement 1. In addition to the situation in FIG. 5, the conveyor arrangement 1 comprises now the junctions J as well as a number of merges M branching off at the junctions J.

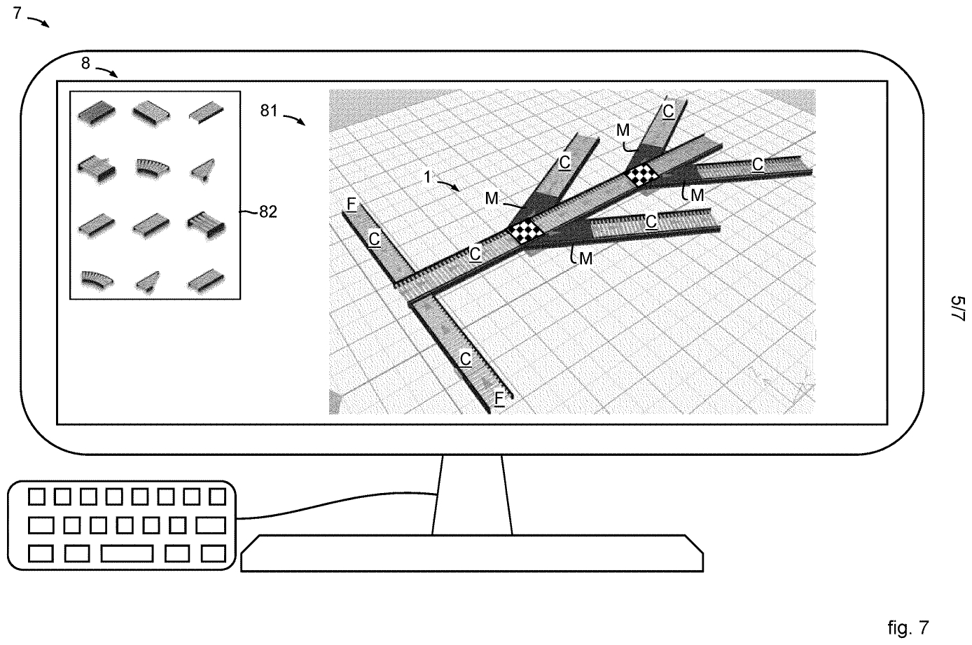

FIG. 7 shows in the construction area 81 the representation of the further developed conveyor arrangement 1. In addition to the situation in FIG. 6, the conveyor arrangement 1 comprises now additional conveyors C downstream of the merges M. Also, the feed in stations F and the connecting conveyors C are provided, which are connected via a junction J to the previous conveyors C.

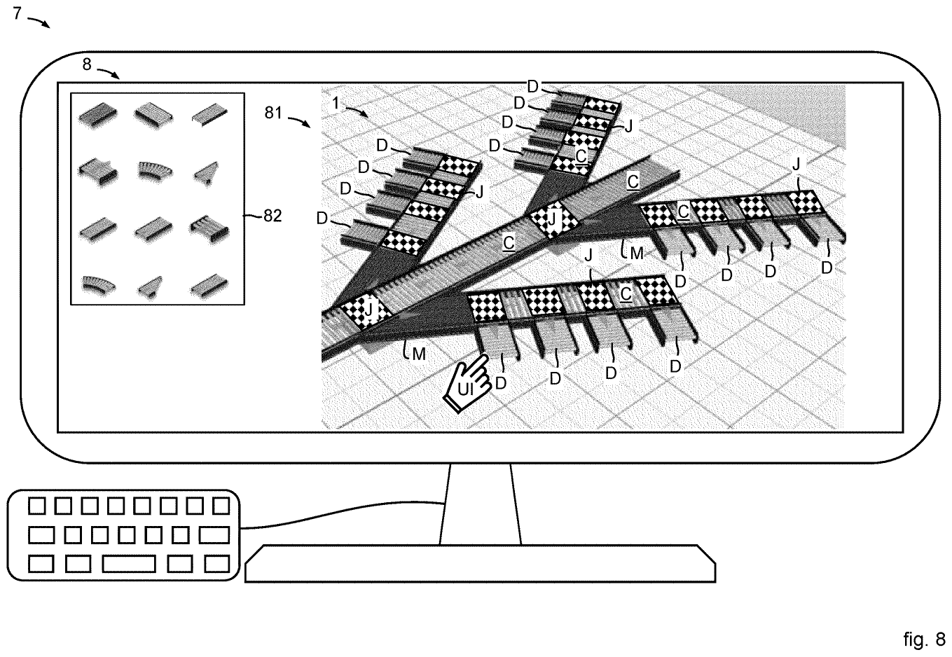

FIG. 8 shows in the construction area 81 the representation of the further developed conveyor arrangement 1. In addition to the situation in FIG. 7, the conveyor arrangement 1 comprises the destinations D branching off from the conveyors C downstream of the merges M. Additional junctions J are provided where the destinations D branching off from previous conveyors. Here the destination D are in the form of roller conveyors.

As can be realized by a comparison between the FIGS. 8 and 7 the focus of the construction area can be varied by the planner.

The junction J can be realized by various embodiments. As an usual embodiment a junction J can be established by a roller conveyor which is equipped with a transfer device such as shown e.g. in FIG. 5 of EP 3 222 564 B1.

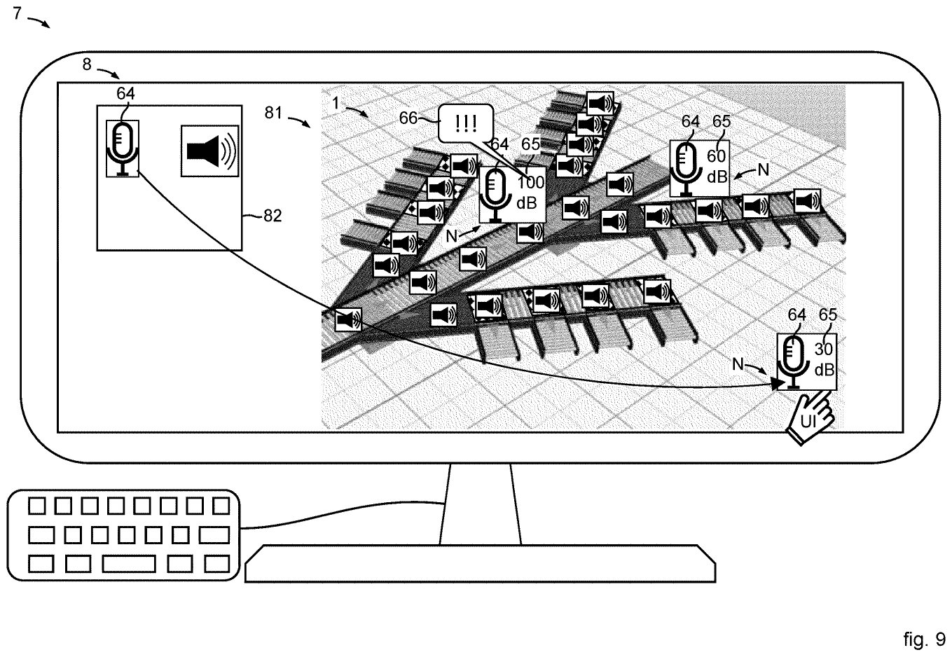

FIG. 9 shows the layouter in another planning situation. Here a representation of a completed conveyor arrangement 1 is shown within the construction area 81. In the selection area 82 a representation of a virtual microphone 64 is provided, which can be selected and positioned by the planner. By an user interaction UI, the virtual microphone 64 can be placed anywhere in the construction area 81 in spatial relation to the conveyor arrangement 1. Within the present description the position where the virtual microphone is positioned is called the “noise position N”. So, by performing the placing of the virtual microphone 64 at a certain position, a noise position N is defined by means of a user interaction UI.

In an alternative embodiment the noise position N is defined without a direct user interaction UI. During the intended use of the conveyor arrangement 1 an operator person is interacting with the conveyor. For example, the operator may manually pick objects from the conveyor or put objects onto the conveyor in particular at a destination D. Thereby the operator is located at an operator position. The operator position may automatically be defined as a noise position N, so as to check the noise level 65, to which an operator is exposed to.

Now, a noise level 65 at a noise position N is determined and displayed. The determined noise level 65 is an indicator of a real noise level 65 at the noise positions N in reality, but deviations may be possible.

As apparent from FIG. 9 there are different noise levels 65 at different noise positions N, which are depending on the components within the conveyor arrangement 1 and the distance between the noise position N and said components.

For determining a noise level 65, individual components of the conveyor arrangement 1 are seen as a noise source of known noise behavior. Therefore, a noise model is allocated to each of the conveyor zones 2. The noise model may be a mathematical model, by which a noise emission behavior can be calculated. Based on the individual locally defined noise sources, a sound propagation of the conveyor arrangement 1 can be determined and thus a noise level 65 at a different noise position N can be determined.

Thereby it is of minor relevance, to which unit of the conveyor arrangement 1 a noise model is allocated. Instead of a conveyor zone 2, the noise model can be allocated to any in particular noisy, component or group of components, e.g. a motor, a transmission, a gear motor, a conveyor roller, a set of conveyor rollers or a belt conveyor assembly.

The result of the above method can be used to determine an estimated noise exposure for an operator located at a particular workplace at the real conveyor arrangement 1. Based on this, suitable protective measures can be defined in a subsequent step, such as wearing of a hearing protection or the provision of noise barriers.

FIG. 9 shows also an alert 66, in case when the determined noise level 65 at a particular noise position N exceeds a predetermined limit.

### LIST OF REFERENCE SIGNS

1 conveyor arrangement
2 conveyor zone
3 conveyor roller
3M motorized conveyor roller
31 drive connector
4 support frame
5 presence sensor
7 PC, personal computer
8 IT tool/layouter
81 construction area
82 selection area
83 graphical representation
9 object to be conveyed
11 local zone controller
12 PLC
13 bus connection
64 virtual microphone
65 noise level
66 alert
C conveyor as an example of a conveyor area
d conveying direction
D destination as an example of a conveyor area
F feed in station as an example of a conveyor area
I inlet
J junction
L line
M merge
N noise position
O outlet
Sc conveyor surface
UI user interaction

1. A method of planning a conveyor arrangement (1), the conveyor arrangement (1) is adapted to convey an object (9) from at least one first location (F) to at least one second location (D);
wherein the method comprising the following step of providing an IT planning tool (8) for usage by a planner; wherein by using the IT planning tool (8), representations (83) of a plurality of conveyor components, in particular conveyor zones (2) are arranged in a manner to form a, in particular graphical, representation (83) of said conveyor arrangement (1);
characterized by
the step of outputting a noise level (65) by the IT planning tool (8).

2. The method according to claim 1, characterized in
where the noise level (65) represents an expected noise level at a noise position (N) in a spatial relation to the planned conveyor arrangement (1).

3. The method according to claim 1, characterized by the steps of
defining a noise position (N) in spatial relation to the conveyor arrangement (1),
determining a noise level (65) at the noise position (N).

4. The method according to claim 3, characterized in
that the noise position (N) is defined by an user interaction (UI), in particular by marking a position to be defined as the noise position (N), in particular by placing a symbol at said position.

5. The method according to claim 3, characterized in
that the noise position (N) is defined automatically by the IT tool (8).

6. The method according to claim 1, characterized by the step of
providing a noise model of one or a plurality of conveyor components to determine a noise emission of said one or a plurality of conveyor components,
wherein based
on said determined noise emission, and
a location of said noise emission and
said noise position (N)
the noise level (65) at said noise position (N) is determined.

7. The method according to claim 1, wherein during intended use of the operation an operator interacts with said object (9) located within the conveyor arrangement (1).
